(19) United States
(12) Patent Application Publication
(10) Pub. No.: US 2011/0026555 A1
(43) Pub. Date: Feb. 3, 2011

(54) SURFACE EMITTING LASER, SURFACE EMITTING LASER ARRAY, AND OPTICAL APPARATUS

(75) Inventor: Tetsuya Takeuchi, Yokohama-shi (JP)

Correspondence Address: CANON U.S.A. INC. INTELLECTUAL PROPERTY DIVISION, 15975 ALTON PARKWAY, IRVINE, CA, 92618-3731, US

(73) Assignee: CANON KABUSHIKI KAISHA, Tokyo (JP)

(21) Appl. No.: 12/837,345

(22) Filed: Jul. 15, 2010

(30) Foreign Application Priority Data
Jul. 31, 2009 (JP) 2009-178992

(51) Int. Cl. H01S 5/18; H01S 5/323

(52) U.S. Cl. 372/45.011; 372/50.124

(57) ABSTRACT

A surface emitting laser includes a pair of multilayer mirrors disposed opposing to each other, and an active layer disposed between the multilayer mirrors. In at least one multilayer mirror of the pair of multilayer mirrors, a plurality of first pair layers are stacked, each first pair layer is formed from a high-refractive index layer having a first strain and a low-refractive index layer having a second strain; and a second pair layer is included, the second pair layer is formed of one of the high-refractive index layer and the low-refractive index layer of the first pair layer in which one of the high-refractive index layer and the low-refractive index layer of the first pair layer is replaced with a layer formed from a quaternary or higher mixed crystal semiconductor material having a third strain.

### BACKGROUND OF THE INVENTION

1. Field of the Invention

The present invention relates to a surface emitting laser, a surface emitting laser array, and an optical apparatus including the surface emitting laser array.

2. Description of the Related Art

The surface emitting laser (SEL) is an important device for various optical applications, such as optical communications and electrophotographic printing. A well known type of surface emitting laser is the vertical cavity surface emitting laser (VCSEL). In a surface emitting laser, light can be taken in a direction perpendicular to a semiconductor substrate surface, which facilitates the formation of two-dimensional arrays by merely changing a mask pattern in element formation.

Parallel processing through the use of a plurality of beams emitted from a thus formed two-dimensional array can achieve a high density and a high speed, so that various industrial applications are made possible.

For example, the VCSEL can be used in various optical systems, such as optical networks, parallel optical interconnects, laser printers, high density optical disks and the like. The use of the surface emitting laser array as an exposure light source of an electrophotographic printer can achieve high density processing and high speed in a printing step on the basis of a plurality of beams.

At its most basic concept, the surface emitting laser is formed from an active layer and at least one pair of multilayer mirror sandwiching the active layer vertically.

The multilayer mirror is formed on the basis of repetition of a pair composed of two types of layers having different refractive indices. The thickness of each layer is an optical thickness of a quarter wavelength.

In general, dielectrics and semiconductor materials are used as the multilayer mirror. In the case where the semiconductor is used, a current can be confined to a certain region of the active layer and passed therethrough, by performing selective doping. More specifically, selective doping with an impurity is performed while a crystal is grown on a semiconductor substrate, so that current injection into a region of the active layer is facilitated.

However, it is necessary that a single-crystal layer is produced by growing a crystal and, therefore, materials for constituent layers of the multilayer film semiconductor are limited to materials with lattice match to the substrate. In other words, when using semiconductor materials to form the multilayer mirror, it is necessary that the lattice structure of the materials chosen to form the layers of the multilayer film matches the lattice structure of the substrate.

Furthermore, regarding the use of semiconductor materials and combinations thereof with the above-described lattice match, a large value of difference in refractive index is not obtained as compared with the case in which dielectrics are used. Consequently, it is necessary to increase the number of repetition pairs in order to obtain the reflectivity required for lasing.

As for surface emitting lasers used in practice, infrared surface emitting lasers, which lase in a 850 nm band or a 780 nm band, are mentioned as an example.

A multilayer mirror in the above-referenced infrared laser is formed from pairs of an AlGaAs layer having a high Al composition and an AlGaAs layer having a low Al composition on a GaAs substrate. As compared with GaAs, AlGaAs has a slightly larger lattice constant. For example, even in the case of AlAs having the highest Al composition, lattice mismatch to the GaAs substrate is 0.14%.

If the strain is at such a low level, in general, the material is assumed to be of a lattice match family, and an influence of the strain is at a low level.

However, regarding the surface emitting laser, it is necessary that several tens of multilayer mirror pairs are stacked. Therefore, even if each strain is at a low level, a total thickness of layers having the strain becomes very large and, thereby, accumulation of the strain exerts a large effect.

A red surface emitting laser, which lases in a 680 nm band, is taken as another example. In this element, layers of AlGaAs with a lattice structure that substantially matches that of the GaAs substrate is used for the multilayer mirror. Since it is necessary to select AlGaAs having an Al composition exhibiting no absorption at the lasing wavelength, for example, Al_{0.5}Ga_{0.5}As/Al_{0.9}Ga_{0.1}As or Al_{0.5}Ga_{0.5}As/AlAs is selected as a combination. Consequently, the average Al composition is 0.7 or more and, therefore, is large as compared with that in the case of infrared. This results in about 0.1% in terms of the amount of strain.

Furthermore, the difference in refractive index is small and, therefore, it becomes necessary to increase the number of pairs in order to ensure the reflectivity necessary for lasing. Specifically, about 30 pairs are required in the side where light is taken, about 60 pairs are required in the side where light is not taken and, therefore, the total thickness becomes close to 10 μ.

In this case, the amount of accumulated strain, which is the sum total of the individual products of the amount of strain and a thickness of film having the strain, becomes a large value of 0.1%×10 μm=1%·μm. Examples, in which the strain is used actively, include a strained quantum well structure.

In this example, a layer having a relatively large strain of 1% is used in general. However, the layer thickness thereof is about 50 nm at the maximum in spite of being multi-quantum wells and the amount of accumulated strain is an incomparably smaller value of 0.05%·μm at the maximum.

Warping of an epitaxial wafer occurs because of this large accumulated strain. As for a GaAs substrate having a thickness of 650 μm, it is estimated by calculation that warping with a curvature radius of up to 7 m occurs. The AlGaAs layer has a lattice constant slightly larger than that of the GaAs substrate and, therefore, the epitaxial wafer warps into a convex shape.

The value of curvature radius of 7 m corresponds to generation of a gap of about 70 μm in the center of a 3-inch wafer.

In the case where warping of the wafer is measured actually, a gap of 70 to 80 μm is generated. Consequently, it is clear that the substrate is warped into a convex shape because of the accumulated strain.

In the case where warping occurs in the wafer, as described above, pattern deviation may occur in alignment in a photolithography step or variations in temperature distribution may occur in a wafer heating step during a process, so as to lead to yield reduction in element formation.

Moreover, it is significantly feared that internal presence of accumulated strain exerts an influence on the reliability.

Some methods have been proposed as measures against the above-described warping of the substrate. For example, Japanese Patent Laid-Open No. 2003-37335 and Japanese Patent Laid-Open No. 2006-310534 have proposed methods, in which regarding a pair constituting a multilayer mirror, materials mutually compensating a strain in the pair are selected.

In these methods, for example, a technique, in which in the case where a layer having a compressive strain, e.g., AlGaAs on a GaAs substrate, is selected as one layer of the pair, a layer having a tensile strain is used as the other layer, is adopted.

Specifically, the thicknesses of constituent layers of the multilayer mirror are made to have the same optical thickness of a quarter wavelength. To be precise, the layer thicknesses are different depending on the magnitude of the refractive index. However, as for the semiconductor materials, difference in refractive index is not significant, and the individual layer thicknesses are nearly the same. For example, as for the red surface emitting laser, the optical thickness of a quarter wavelength is about 50 nm.

Therefore, in order to compensate for the strains, it is enough that the individual strains in the layers constituting the pair have nearly the same absolute values and are of opposite sign, that is, opposite in direction.

However, in this case, it is desirable that not only the layers having nearly equal strains of opposite sign are disposed, but also the layers are formed from materials exhibiting no absorption at the lasing wavelength, sufficient difference in refractive index, and good electrical conductivity based on doping.

As for materials satisfying the above-described conditions at the same time, there is a limit to binary or ternary semiconductor materials.

FIG. 3 is a schematic diagram for explaining the relationship between the band gap and the lattice constant in the binary, ternary, and quaternary materials.

In FIG. 3, the vertical axis indicates the band gap, and the horizontal axis indicates the lattice constant. Put another way, the vertical axis indicates the refractive index, and the horizontal axis indicates the amount of strain.

As shown in FIG. 3, regarding the binary material, the relationship between the refractive index and the amount of strain is represented by points and is univocally defined.

Even in the case where the ternary material is concerned, the relationship between the refractive index and the amount of strain is represented by lines and cannot be controlled independently.

The relationship between the refractive index and the amount of strain is represented by a plane and the two can be controlled independently only in the case where a quaternary or higher material is used.

As described above, the relationship between the refractive index and the amount of strain is represented by a plane and the two can be controlled independently only in the case where a quaternary or higher material is used. However, the heat resistance of a quaternary or higher mixed crystal material is high as compared with that of a binary or ternary material.

Consequently, an element formed by using a quaternary or higher material has problems in that the heat resistance becomes large, heat dissipation is small, the internal temperature of the element is raised and, along with that, the element characteristics are degraded.

In particular, regarding a red surface emitting laser having a poor temperature characteristic, an increase in heat resistance leads to significant degradation of the element characteristics, so that even if the problems due to the accumulated strain can be solved, intrinsic requirements concerning the element characteristics are not satisfied.

### SUMMARY OF THE INVENTION

In consideration of the above-described problems, the present invention provides a surface emitting laser, a surface emitting laser array, and an optical apparatus, in which an occurrence of warping of a substrate is eliminated or at least minimized by using a quaternary or higher material. In addition, a significant increase in heat resistance can be prevented, so as to suppress degradation of basic characteristics of an element due to heat.

The present invention provides a surface emitting laser having a configuration described below. A surface emitting laser according to the present invention includes a pair of multilayer mirrors disposed opposing to each other; and an active layer disposed between the multilayer mirrors, wherein, in at least one multilayer mirror of the pair of multilayer mirrors,
a plurality of first pair layers are stacked, each first pair layer being formed from a high-refractive index layer having a first strain and a low-refractive index layer having a second strain, and
a second pair layer is included, the second pair layer being formed of one of the high-refractive index layer and the low-refractive index layer of the first pair layer in which one of the high-refractive index layer and the low-refractive index layer of the first pair layer is replaced with a layer formed from a quaternary or higher mixed crystal semiconductor material having a third strain,
the sum of the first strain and the second strain is a compressive or tensile strain, and
the third strain is reverse to the sum of the first strain and the second strain and the absolute value of the third strain is larger than the absolute values of the first strain and the second strain.

According to the present invention, a surface emitting laser, a surface emitting laser array, and an optical apparatus can be realized, wherein an occurrence of warping of a substrate is eliminated by using a quaternary or higher material and, in addition, a significant increase in heat resistance can be prevented, so as to suppress degradation of basic characteristics of an element due to heat.

Further features of the present invention will become apparent to persons of ordinary skill in the art from the following description of exemplary embodiments with reference to the attached drawings.

### BRIEF DESCRIPTION OF THE DRAWINGS

FIG. 1 is a schematic sectional view of a vertical cavity surface emitting laser according to Example 1 of the present invention.

FIG. 2 is a schematic sectional view of an n-type multilayer mirror in Example 1 according to the present invention.

FIG. 3 is a schematic diagram showing the relationship between the band gap and the lattice constant in binary, ternary, and quaternary materials.

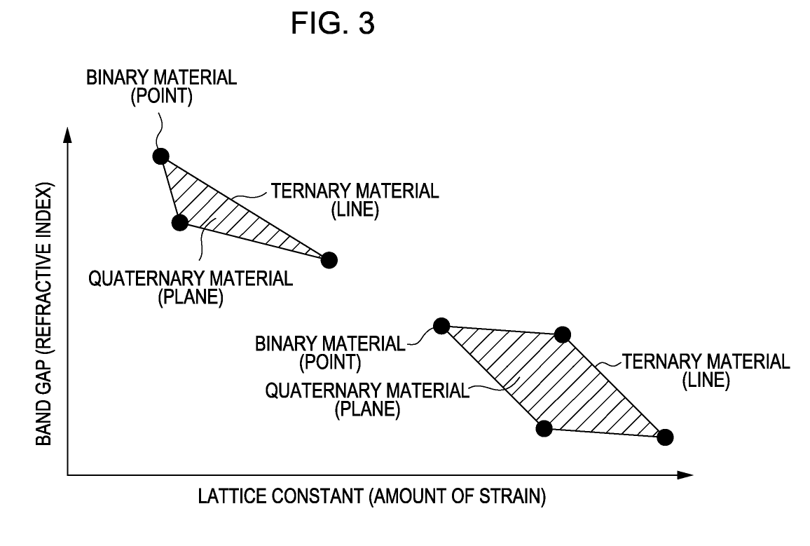

FIG. 4 is a diagram showing the dependence of the relationship between the amount of strain of a strain compensation layer and an average amount of strain in a strain compensation unit structure on the number of pairs.

FIG. 5 is a schematic sectional view of a vertical cavity surface emitting laser according to Example 2 of the present invention.

FIG. 6 is a schematic sectional view of an n-type multilayer mirror, for explaining a specific arrangement configuration of AlGaInP layers in Example 2 according to the present invention.

FIG. 7 is a schematic sectional view of a vertical cavity surface emitting laser according to Example 3 of the present invention.

FIG. 8 is a schematic sectional view of an n-type multilayer mirror, for explaining a specific arrangement configuration of AlGaInP layers in Example 3 according to the present invention.

FIG. 9 is a schematic sectional view of an n-type multilayer mirror in Example 4 according to the present invention.

FIGS. 10A and 10B are schematic diagrams for explaining a configuration example of an optical apparatus formed by applying a vertical cavity surface emitting laser in Example 5 according to the present invention.

FIG. 11 is a diagram showing the relationship between the strain and the refractive index in a configuration example, in which predetermined amounts of In composition, Al composition, and Ga composition are used for an AlGaInP layer in Example 1 according to the present invention.

FIG. 12 is a diagram showing the relationship between the strain and the refractive index in a configuration example, in which predetermined amounts of In composition, Al composition, and Ga composition are used for an AlGaInP layer in Example 4 according to the present invention.

### DESCRIPTION OF THE EMBODIMENTS

According to the above-described configuration of the present invention, a surface emitting laser having excellent element characteristics can be provided. In such a novel element, an occurrence of warping of a substrate is eliminated or at least minimized by reducing an accumulated strain resulting from lattice mismatch and, in addition, the heat resistance does not increase significantly.

Next, the embodiments according to the present invention, as well as the principle thereof, will be described with reference to an AlGaAs multilayer structure on a GaAs substrate, serving as a multilayer mirror for a red surface emitting laser.

It is desirable that in the multilayer mirror on the side where light is not taken, the reflection loss is minimized, that is, the reflectivity is increased. Therefore, the multilayer mirror including about 60 pairs of layers is used.

Here, constituting a first pair layer, Al_{0.5}Ga_{0.5}As is used as a high-refractive index layer and AlAs is used as a low-refractive index layer.

On the basis of lattice mismatch to the GaAs substrate, Al_{0.5}Ga_{0.5}As of the high-refractive index layer has 0.07% of compressive strain (first strain) and AlAs of the low-refractive index layer has 0.14% of compressive strain (second strain). Each layer thickness is a thickness corresponding to an optical thickness of a quarter wavelength.

Here, a simple optical thickness of a quarter wavelength is used. However, in order to improve the electrical conductivity of the multilayer mirror in itself, about 10 to 20 nm of compositionally graded layer may be disposed between the high-refractive index layer and the low-refractive index layer.

In the case where 60 pairs of the above-described first pair layers are stacked, the amount of accumulated strain becomes

(0.07+0.14)×0.05×60=0.63%·μm

because each optical thickness of a quarter wavelength is about 50 nm.

In the present embodiment, in order to compensate for the accumulated strain, one of the above-described high-refractive index layers and the above-described low-refractive index layer in any one of the 60 first pair layers is replaced with a layer formed by selecting a quaternary or higher mixed crystal semiconductor material.

That is, a second pair layer is formed on the basis of pairing with the layer, in which one of the above-described high-refractive index layers and the above-described low-refractive index layer in any one of the above-described first pair layers is replaced with a layer formed from a quaternary or higher mixed crystal semiconductor material.

In this regard, the first pair layer is formed from a binary semiconductor material or a ternary semiconductor material; and the second pair layer is formed from a quaternary or higher semiconductor material. For the layers in the first pair layer, the exemplary materials described herein or any material known to those of ordinary skill in the art can be utilized. Furthermore, for the second pair layer, AlGaInP is selected here merely as an example of the quaternary material capable of obtaining a lattice constant in the vicinity of the GaAs substrate. Other quaternary or higher semiconductor materials should be selected on the basis of the strain in the binary or ternary materials selected for the first pair layers.

Next, the strain to be introduced into AlGaInP described above will be explained.

In this example, an Al_{0.5}Ga_{0.5}As/AlAs pair constituting the multilayer mirror has a compressive strain as the accumulated strain. Therefore, it is necessary that the strain (third strain) of the layer formed from the quaternary or higher mixed crystal semiconductor material is a tensile strain, which is the strain in the reverse direction.

Then, regarding the magnitude, if too large strain is introduced, the crystallinity is degraded; and if the strain is too small, compensation for the strain with a reduced number of layers, which is intended by the present invention, cannot be achieved. In any event, it is necessary that the absolute value of the third strain is larger than the absolute values of the above-described first strain and the second strain.

From the viewpoint of the crystallinity, if the strain exceeds 2%, degradation is significant and, therefore, 2% or less is preferable. More preferably, the strain is 1% or less, and 0.6% or less is further preferable.

Here, a tensile strain is assumed to be 0.6%. The layer thickness is an optical thickness of a quarter wavelength and, therefore, is about 50 nm.

Then, a layer to be replaced with the AlGaInP layer having the above-described strain (about 0.6%) and layer thickness (about 50 nm) is selected.

In the present embodiment, the AlGaInP layer to compensate for the strain does not necessarily have a function as a multilayer mirror. However, in the case where the function is provided positively, the whole multilayer mirror can be formed having a smaller layer thickness efficiently.

More specifically, during the fabrication process it is recommended that in the replacement layer be properly decided whether the AlGaInP layer to compensate for the strain is used as the high-refractive index layer of the multilayer mirror or is used as the low-refractive index layer.

For example, the AlGaInP layer is used as the low-refractive index layer so as to replace a layer having a larger amount of strain (here, AlAs low-refractive index layer).

Alternatively, the AlGaInP layer may be used so as to replace a layer (here, Al_{0.5}Ga_{0.5}As high-refractive index layer) in such a way that reduction in refractive index is not introduced and the same refractive index can be achieved easily. In any event, design flexibility based on the quaternary or higher material is used effectively and selection is conducted in such a way that desired characteristics are obtained.

Here, the AlGaInP layer is used so as to replace the Al_{0.5}Ga_{0.5}As high-refractive index layer in such a way that the refractive index becomes equal.

As for a material having nearly the same refractive index as that of Al_{0.5}Ga_{0.5}As and lattice-matching to the GaAs substrate, Al_{0.25}Ga_{0.25}In_{0.5}P is mentioned.

However, the proportions in Al_{0.25}Ga_{0.25}In_{0.5}P may be considered to be the reference from which In may be reduced from 0.5, and the total of Al and Ga may be increased correspondingly from 0.5, so as to achieve a tensile strain of 0.6%.

Next, the number of pairs, which can be compensated, is determined.

The resulting number of pairs is assumed to be n. There are n layers of AlAs layers, and (n−1) layers of Al_{0.5}Ga_{0.5}As layers are present because only one layer thereof is replaced with the AlGaInP layer.

The condition of compensation for strain is that the amount of accumulated strain of these layers and one layer of AlGaInP layer becomes nearly zero. Therefore, the following formula holds:

ε₁×t₁×n+ε₂×t₂×(n−1)+ε₃×t₃×1=0 Formula 1

where
ε₁: amount of strain of AlAs layer
t₁: layer thickness of AlAs layer
ε₂: amount of strain of Al_{0.5}Ga_{0.5}As layer
t₂: layer thickness of Al_{0.5}Ga_{0.5}As layer
ε₃: amount of strain of AlGaInP layer
t₃: layer thickness of AlGaInP layer.

Regarding the strain, opposite directions are indicated by opposite signs. Here, the compressive strain is assumed to be negative, and the tensile strain is assumed to be positive.

In the case where Formula 1 is solved on the basis of the numerical values in the above-described example, a solution thereto is n=3. Therefore, one layer of the above-described AlGaInP layer can compensate for 3 pairs of AlGaAs multilayer mirrors. This 3-pair structure constitutes the minimum unit in compensation for the strain and, therefore, this minimum pair structure for performing strain compensation is assumed to be a strain compensation unit structure.

The number of required quaternary material layers is reduced to one-third of that in the case where strain compensation is conducted on a pair basis, and an increase in element resistance due to the heat resistance of the quaternary material can be reduced significantly.

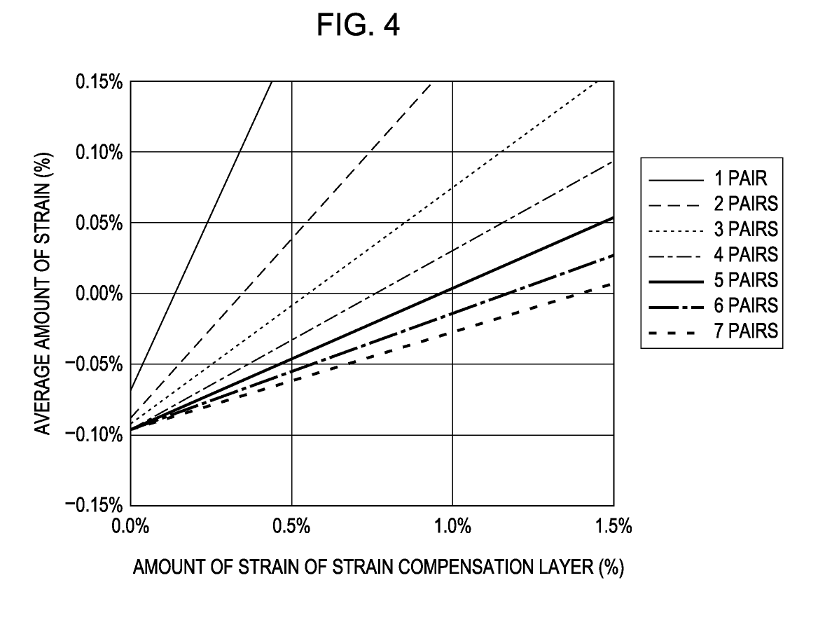

This idea is generalized and can be expressed by a diagram, as shown in FIG. 4, indicating the dependence of the relationship between the amount of strain of a strain compensation layer and an average amount of strain in a strain compensation unit structure on the number of pairs.

Here, cases are sorted according to the number of pairs in the strain compensation unit structure.

In FIG. 4, the horizontal axis indicates the amount of strain of the AlGaInP strain compensation layer and the vertical axis indicates the average amount of strain of each strain compensation unit structure.

The average amount of strain is a value determined by normalizing the amount of accumulated strain concerned with a total layer thickness. If the average amount of strain is 0, the amount of accumulated strain also becomes 0 and, thereby, the substrate warping problem, and the like are eliminated.

As shown in FIG. 4, in the case where the strain compensation unit structure includes 2 pairs, the AlGaInP layer is required to have an amount of tensile strain of 0.4%.

Furthermore, as for 3 pairs, the amount is 0.6%, as described above. As for 4 pairs, the amount is 0.8%. As for 5 pairs, the amount is 1.0%. As for 6 pairs, the amount is 1.2%. As for 7 pairs, the amount is 1.4%.

Finally, an operation to incorporate this strain compensation unit structure into a multilayer mirror structure in an epitaxial wafer is required.

Here, a case of a strain compensation unit structure including 3 pairs is taken as an example.

Initially, the 3 pairs are literally assumed to be the unit structure and are stacked periodically, so as to form 60 pairs.

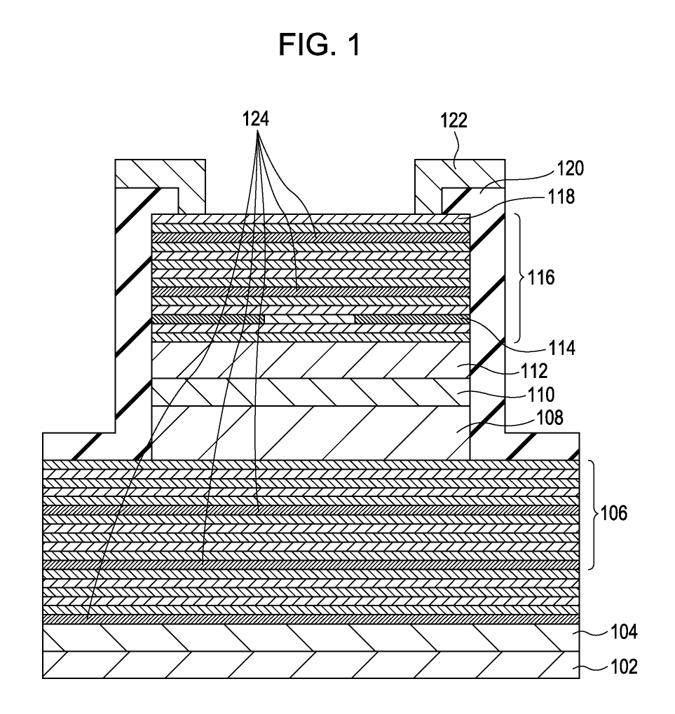

This configuration is schematically expressed as the configuration shown in FIG. 1.

In this case, there is no large variation in warping of a substrate during the growth of crystal, and variations in temperature distribution can be minimized during the growth of crystal.

In this case, the number of stacking of the strain compensation unit structures becomes just an integer (20), although it is not always an integer. In this case, the accumulated strain does not become completely zero. However, the value merely corresponds to a value in the case where strain compensation is not conducted with respect to a layer thickness of the strain compensation unit structure at the maximum. Therefore, the value is incomparably small value as compared with the amount of warping of the substrate concerned, so that the effect of the present invention is obtained sufficiently even in this case.

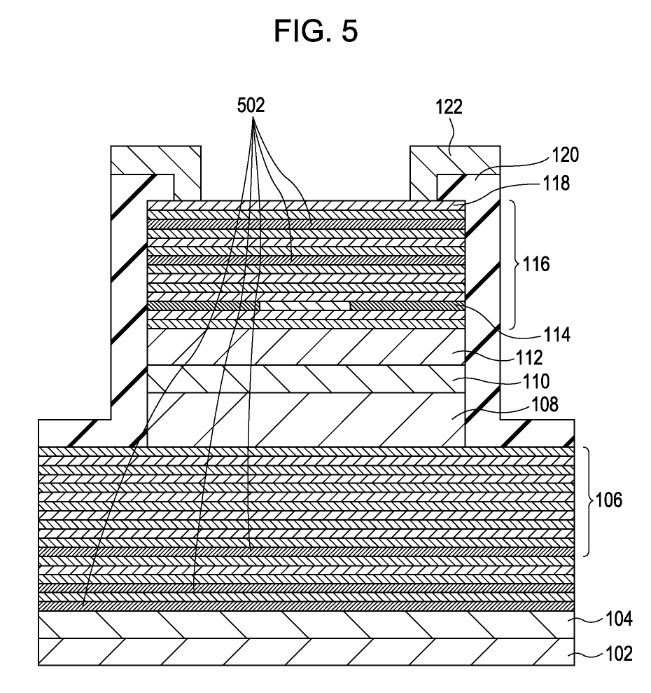

On the other hand, in order to further reduce the heat resistance, the quaternary or higher material having high heat resistance may be disposed further apart from the active layer. This configuration can be schematically expressed as the configuration shown in FIG. 5.

The concept of the strain compensation in this case is as described below. In the side farther from the active layer, the AlGaInP layer is inserted frequently on a pair basis.

Under this condition, the substrate undergoes a tensile accumulated strain and comes into the state of being warped concavely. Then, regarding the structure, the AlGaInP layer is hardly inserted with increasing proximity to the active layer.

In this case, if the total number of inserted AlGaInP layers is made equal to that in the case where one AlGaInP layer is inserted every 3 pairs, regarding the amount of accumulated strain of the whole multilayer mirror, the same effect as the strain compensation effect obtained by stacking the strain compensation unit structures is obtained.

Consequently, warping of the substrate does not occur in the state, in which all layers of the multilayer mirrors have been formed.

If the quaternary or higher material having high heat resistance is disposed at a location further apart from the active layer, the heat resistance in the vicinity of the active layer, on which the heat is concentrated, is not increased practically, and a temperature increase in the active layer after formation of the element can be minimized.

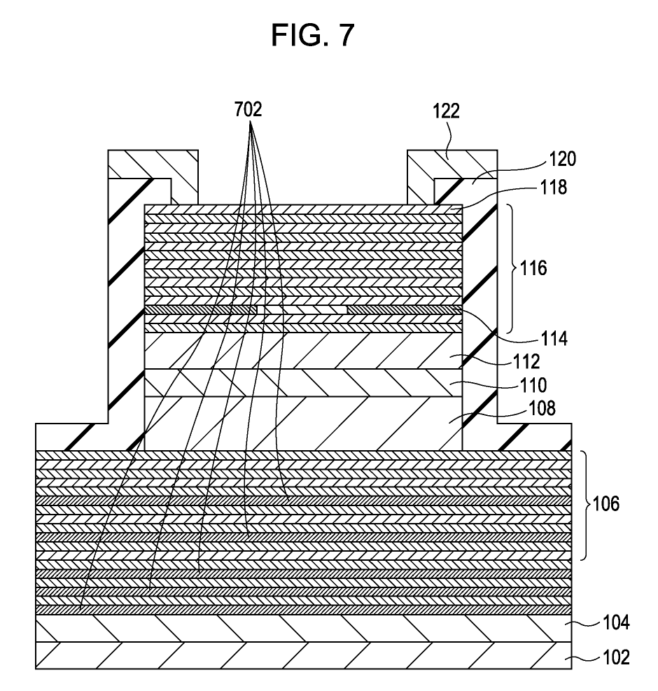

Furthermore, in general, the quaternary or higher mixed crystal semiconductor materials, e.g., AlGaInP, are affected by mixed crystal scattering to a greater extent, so that the mobility is reduced and, in particular, electrical conductivity of the p-type is degraded. Moreover, materials containing P and N as constituent elements and having wide band gaps are inherently difficult to convert to the p type. On the other hand, it has been known that good n-type conductivity is obtained. Consequently, in order to suppress an increase in electrical resistance of the element, it is possible to dispose the quaternary or higher mixed crystal semiconductor material in the n-type multilayer mirror in an amount more than or equal to the amount required for compensating for the accumulated strain in the p-type multilayer mirror. This configuration can be schematically expressed as the configuration shown in FIG. 7. In this case as well, the total number of inserted AlGaInP layers is not changed and an equivalent strain compensation effect is obtained.

Methods for disposing these AlGaInP layers may be selected in accordance with the purpose and the necessity. Here, explanation has been made with reference to the red surface emitting laser as an example. Therefore, the AlGaInP layer has been taken as an example of the quaternary or higher semiconductor layer. However, any quaternary or higher materials may be employed, insofar as the band gap (refractive index) and the lattice constant can be controlled independently.

Examples of candidates include AlGaInP and AlGaInAsPN. Furthermore, regarding a GaN based surface emitting laser of smaller wavelength side, quaternary materials, e.g., AlGaInN, are mentioned.

According to the above-described configuration of the present embodiment, warping of the substrate is eliminated by using a quaternary or higher semiconductor material having high design flexibility, wherein desired band gap and refractive index are obtained, and a strain necessary and sufficient for compensating for the accumulated strain can be obtained. In addition, a significant increase in heat resistance of the element can be prevented, so as to suppress degradation of basic characteristics of the element due to heat.

In particular, a large effect is exerted on an element having a poor temperature characteristic, e.g., a red surface emitting laser.

Furthermore, according to the configuration of the present embodiment, a surface emitting laser array formed by arraying the above-described surface emitting lasers and an optical apparatus including the surface emitting laser array can be realized.

### EXAMPLES

The examples according to the present invention will be described below.

### Example 1

In Example 1, a configuration example of a vertical cavity surface emitting laser including one pair of multilayer mirrors, which lase at 680 nm and which are disposed opposing to each other, and an active layer disposed between these multilayer mirrors disposed opposing to each other will be described with reference to FIG. 1.

The surface emitting laser according to the present example is provided with an n-type multilayer mirror 106 including AlGaInP quaternary strain compensation layers 124 and p-type multilayer mirror 116 including the AlGaInP quaternary strain compensation layers 124. In this regard, as shown in FIG. 1, the AlGaInP quaternary strain compensation layers 124 are disposed uniformly on a strain compensation unit structure basis regardless of p-type multilayer mirror or n-type multilayer mirror.

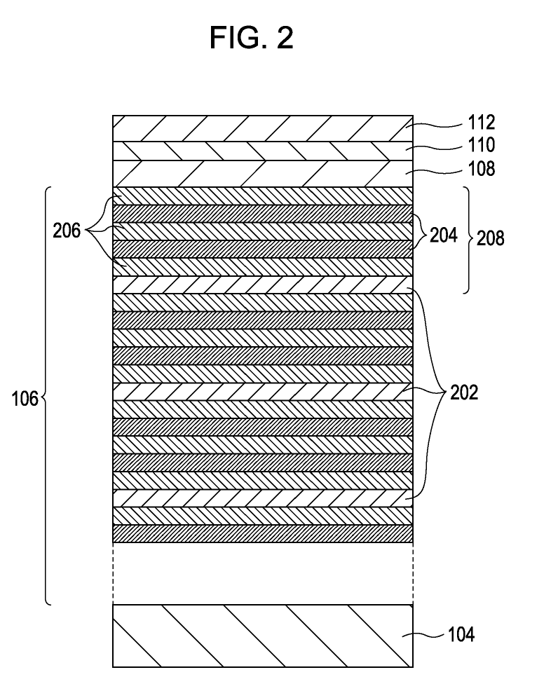

The manner in which quaternary strain compensation layers are formed is shown in detail by a magnified diagram of the n-type multilayer mirror 106 shown in FIG. 2. The n-type multilayer mirror 106 has a structure in which 60 pairs of n-type AlAs low-refractive index layer 206 and n-type Al_{0.5}Ga_{0.5}As high-refractive index layer 204 serving as main constituent layers and each having an optical thickness of a quarter wavelength of the lasing wavelength of 680 nm are stacked.

Here, one n-type AlGaInP strain compensation layer 202 is inserted every 3 pairs of AlGaAs multilayer mirrors, so as to replace one n-type Al_{0.5}Ga_{0.5}As high-refractive index layers 204. This is the strain compensation unit structure 208.

The strain compensation unit structures 208 are stacked by 20 units, so as to achieve the n-type multilayer mirror 106 including 60 pairs.

The p-type multilayer mirror 116 is formed on the basis of the same concept.

However, an oxidized confinement layer 114 is disposed and, therefore, an Al_{0.9}Ga_{0.1}As low-refractive index layer is used as the multilayer mirror instead of the AlAs low-refractive index layer, which is oxidized easily.

Then, the strain in this strain compensation unit structure will be described.

The optical thickness of a quarter wavelength of the AlAs low-refractive index layer is 55.2 nm and the amount of strain is 0.14% in a compression direction. The optical thickness of a quarter wavelength of the Al_{0.5}Ga_{0.5}As high-refractive index layer is 49.6 nm and the amount of strain is 0.07% in a compression direction.

The AlGaInP layer for strain compensation is adjusted in such a way as to have the same refractive index as that of the Al_{0.5}Ga_{0.5}As high-refractive index layer and, therefore, the optical thickness of a quarter wavelength thereof is 49.6 nm.

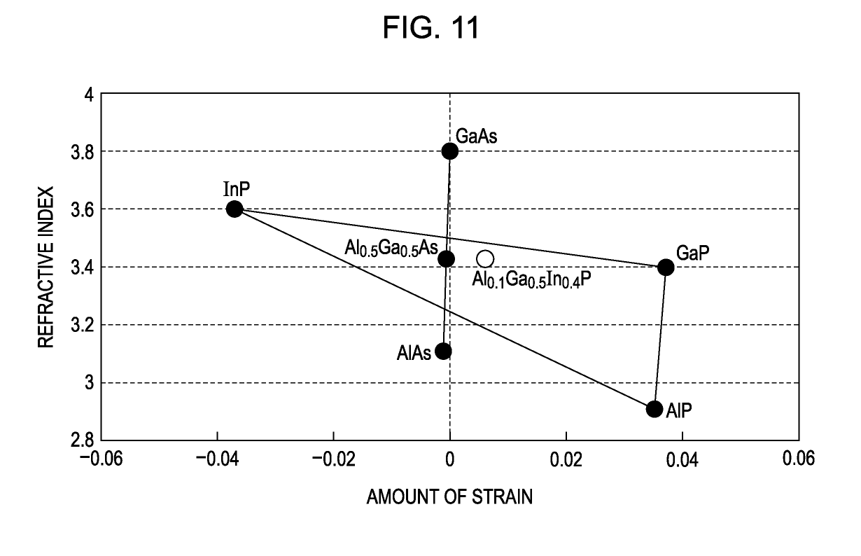

On the other hand, the tensile strain is 0.57%. In order to have such a strain, for example, as for the In composition of the AlGaInP layer, about 40% may be employed, as for the Al composition, about 10% may be employed, and as for the Ga composition, about 50% may be employed. The relationship between the strain and the refractive index at that time is shown in FIG. 11.

As shown in FIG. 11, the refractive index (vertical axis) of the Al_{0.1}Ga_{0.5}In_{0.4}P strain compensation layer is the same as that of the Al_{0.5}Ga_{0.5}As high-refractive index layer. Furthermore, it is clear from comparison with the sum of the strain (horizontal axis) of the Al_{0.5}Ga_{0.5}As high-refractive index layer and the strain of the AlAs low-refractive index layer that the direction (sign, positive indicates a tensile direction and negative indicates a compression direction here) of the strain of this Al_{0.1}Ga_{0.5}In_{0.4}P strain compensation layer is reverse and the absolute value thereof is larger than the sum. The tensile strain of 0.57% is used here. In the case where a tensile strain of, for example, 1% is employed, as described above, as for the In composition, 35% may be used.

In the above-described case, the amount of accumulated strain in the strain compensation unit structure is determined by using the left side of Formula 1 described above.

(−0.14)×0.0552×3+(−0.07)×0.0496×2+0.57×0.0496×1=−0.00029%·μm

Here, as for the multilayer mirrors, 30 pairs are used on the p side, and 60 pairs are used on the n side, so that 10 strain compensation unit structures described above are required in the p side, and 20 strain compensation unit structures are required in the n side. Consequently, 30 strain compensation unit structures are required in total.

In the case where the AlGaInP strain compensation layers are noted, 10 layers are employed in the p side, 20 layers are employed in the n side, and 30 layers are employed in total. Therefore, the amount of accumulated strain of the whole element becomes −0.0086%·μm. In the case where a 3-inch substrate is assumed, the gap at the wafer center due to wafer warping is reduced significantly to 0.6 μm.

As described above, the accumulated strain in a usual case without strain compensation is −1.0%·μm, and the gap at the wafer center is about 70 μm. Therefore, each of them is reduced by a factor of 100.

In addition, it is necessary that the multilayer mirror has the electrical conductivity in order to facilitate current injection into the active layer.

Regarding the n-type multilayer mirror 106, in order to obtain n-type conductivity, the AlGaAs layer and the AlGaInP strain compensation layer are doped with Si or Se.

Regarding the p-type multilayer mirror 116, in order to obtain p-type conductivity, the AlGaAs layer is doped with C or Zn.

On the other hand, the AlGaInP strain compensation layer is doped with Mg or Zn, so as to obtain the p-type conductivity. In order to further reduce the electrical resistance, a compositionally graded layer may be disposed between the two different refractive index layers. In order to reduce the electrical resistance while optical absorption is reduced, modulation doping, in which the amount of doping is reduced in the vicinity of the antinode of light intensity distribution and the amount of doping is increased at the node, and the like may be used.

In the p-type multilayer mirror 116, one of the p-type Al_{0.9}Ga_{0.1}As low-refractive index layers close to the active layer is replaced with a p-type Al_{0.98}Ga_{0.02}As oxidized confinement layer 114. This layer is selectively oxidized under a high-temperature steam atmosphere, so as to be insulated from an element periphery portion, and thereby current confinement structure, in which a current passes only a central portion, is formed.

The active layer 110 has a multiple quantum well structure formed from a plurality of GaInP quantum well layers and a plurality of Al_{0.25}Ga_{0.25}In_{0.5}P barrier layers.

The layer thicknesses of an n-type AlGaInP spacer layer 108 and a p-type AlGaInP spacer layer 112 are adjusted in such a way that the multiple quantum well structure is located at the antinode of an internal light standing wave. As for a resonator formed from them, the layer thicknesses are adjusted in such a way as to have an optical thickness of an integral multiple of the lasing wavelength of 680 nm.

The wavelength of the light emitted from the active layer in itself is adjusted and produced in such a way as to have a light emission peak wavelength (for example, 660 to 670 nm) in the smaller wave side as compared with the resonant wavelength of the surface emitting laser resonator.

A required insulating film 120 is accumulated, patterning is conducted again to expose a part of a p-type GaAs contact layer 118. A ring-shaped Ti/Au is evaporated thereon, so as to form a p-side electrode 122.

Thereafter, AuGe/Ni/Au is evaporated on the back surface of an n-type GaAs substrate 104, and annealing is conducted at about 400° C., so as to form an n-side electrode 102.

Finally, a chip having a required size is cut, die bonding to a package is conducted, and the p-side electrode is wire-bonded, so as to complete an element.

In this regard, a mask is designed for an array appropriately and, thereby, not only an array, in which a single element is disposed, but also an array, in which a plurality of elements are two-dimensionally disposed, can be produced. As described above, it is an advantage of the surface emitting laser that an array structure is obtained relatively easily by merely changing a mask.

According to the configuration of the present example described above, the element can be formed at a high yield, wherein an occurrence of warping of the substrate is eliminated and, in addition, an increase in heat resistance of the element can be prevented, so as to suppress degradation of characteristics due to heat.

### Example 2

In Example 2, a vertical cavity surface emitting laser including one pair of multilayer mirrors, which lase at 680 nm and which are disposed opposing to each other, and an active layer disposed between these multilayer mirrors disposed opposing to each other will be described with reference to FIG. 5.

In FIG. 5, the same configurations as those shown in FIG. 1 are indicated by the same reference numerals as those set forth above. Accordingly, further explanations thereof will not be provided, and only different structures will be explained.

In FIG. 5, reference numeral 502 denotes an n-type AlGaInP strain compensation layer. This layer in itself is the same as the n-type AlGaInP strain compensation layer 124 shown in FIG. 1, but arrangements in the p-type multilayer mirror and the n-type multilayer mirror are different from each other.

Here, in order to minimize the effect of heat on the GaInP strained quantum well active layer 110, a larger number of quaternary strain compensation layers are disposed in places far from the active layer and a smaller number of quaternary strain compensation layers are disposed in the vicinity of the active layer.

Specific arrangement configuration will be described below.

In the present example, the accumulated strain in each of the n-type and p-type multilayer mirrors is adjusted to be zero.

That is, as in Example 1, 20 layers of AlGaInP strain compensation layers in total are required in 60 pairs in the n-type multilayer mirror.

On the other hand, 10 layers of AlGaInP strain compensation layers in total are required in 30 pairs in the p-type multilayer mirror.

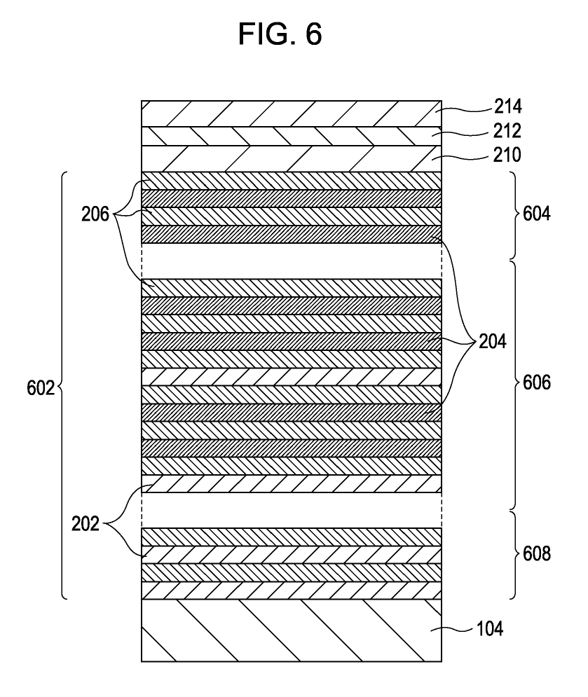

Specific arrangement of these AlGaInP layers is shown in FIG. 6.

In FIG. 6, an n-type multilayer mirror 602 is divided into three regions including a region I 604, a region II 606 and a region III 608, in that order, starting from the side nearest to the active layer, which is the side farthest from the substrate. Here, the region I is formed from 30 combinations of a low-refractive index layer and a high-refractive index layer. Each of the region II and the region III is formed from 15 combinations.

The region I nearest to the active layer is formed from combinations of an n-type AlAs low-refractive index layer and an n-type Al_{0.5}Ga_{0.5}As high-refractive index layer, and no AlGaInP strain compensation layer having high heat resistance is included. That is, the region I 604 includes a predetermined number of n-type low-reflective index layers and n-type high-reflective index layers, but excludes a strain compensation layer.

In the region II, 5 structures basically composed of 2 layers of n-type AlAs low-refractive index layer/n-type Al_{0.5}Ga_{0.5}As high-refractive index layer pair and 1 layer of n-type AlAs low-refractive index layer/n-type AlGaInP strain compensation layer pair are stacked periodically.

Put another way, 5 strain compensation basic structures composed of 3 pairs are stacked.

The region III is formed from combinations of the n-type AlAs low-refractive index layer and the n-type AlGaInP strain compensation layer.

In the n-type multilayer mirror 602, the AlGaInP strain compensation layer is not included in the region I, 5 layers are included in the region II, 15 layers are included in the region III. In other words, in the n-type multilayer mirror 602, 20 AlGaInP strain compensation layers are included in total.

The total number of the AlGaInP layers in the n side becomes equal to the value in Example 1, and the amount of accumulated strain becomes nearly equal to zero as in Example 1.

As for a p-type multilayer mirror, the AlGaInP layers are disposed on the basis of a similar concept. The p-type multilayer mirror is also divided into three regions including a region I, a region II, and a region III in that order from the side nearest to the active layer, as described above.

The number of combinations of layers having different refractive indices is 10 groups in the region I, 15 groups in the region II, and 5groups in the region III.

In the region I, 10 groups are formed from combinations of the p-type Al_{0.9}Ga_{0.1}As low-refractive index layer and the p-type Al_{0.5}Ga_{0.5}As high-refractive index layer, and no AlGaInP strain compensation layer having high heat resistance is included.

In the region II, 5 structures basically composed of 2 layers of p-type Al_{0.9}Ga_{0.1}As low-refractive index layer/p-type Al_{0.5}Ga_{0.5}As high-refractive index layer pair and 1 layer of p-type Al_{0.9}Ga_{0.1}As low-refractive index layer/p-type AlGaInP strain compensation layer pair are stacked periodically.

Put another way, 5 strain compensation basic structures composed of 3 pairs are stacked to form the region II.

In the region III, 5 groups are formed from combinations of the p-type Al_{0.9}Ga_{0.1}As low-refractive index layer and the p-type AlGaInP strain compensation layer.

In the p-type multilayer mirror, the AlGaInP strain compensation layer is not included in the region I, 5 layers are included in the region II, 5 layers are included in the region III. Therefore, in the p-type multilayer mirror, 10 AlGaInP strain compensation layers are included in total.

The total number of the AlGaInP layers in the p side becomes equal to the value in Example 1, and the amount of accumulated strain becomes nearly equal to zero as in Example 1.

As described above, in the present example, the AlGaInP layers, which are necessary from the viewpoint of strain compensation but which are not desirable from the viewpoint of heat resistance, are preferably disposed at locations far from the active layer.

Consequently, the surface emitting laser element can be realized, wherein an occurrence of warping of the substrate is eliminated without increasing the heat resistance in the vicinity of the active layer and, in addition, degradation of element characteristics is reduced.

### Example 3

In Example 3, a vertical cavity surface emitting laser, which lases at 680 nm will be described with reference to FIG. 7. The vertical cavity surface emitting laser of the present example includes one pair of multilayer mirrors disposed opposing to each other and an active layer disposed between the multilayer mirrors.

In FIG. 7, the same configurations as those shown in FIG. 1 are indicated by the same reference numerals as those set forth above. Accordingly, further explanations thereof will not be provided, and only different structures will be explained. In FIG. 7, reference numeral 702 denotes an n-type AlGaInP strain compensation layer. The strain compensation layer 702 is of the same structure as the n-type AlGaInP strain compensation layer 124 shown in FIG. 1, but the arrangement in the multilayer mirror is different.

In the present example, in order to minimize the effect of heat on the GaInP strained quantum well active layer 110, a larger number of quaternary strain compensation layers are disposed in places far from the active layer 110.

Then, a smaller number of quaternary strain compensation layers are disposed in the vicinity of the active layer 110. In addition, in order to obtain better electric characteristics at the same time, all the AlGaInP layers to compensate for the accumulated strain of the p-type multilayer mirror are disposed only in the n-type multilayer mirror.

Specific arrangement configuration will be described below.

In the present example, the accumulated strain of all the element structures is adjusted to become zero by the AlGaInP strain compensation layers in the n-type multilayer mirror.

That is, as in Example 1, the number of AlGaInP layers is 30 layers, although all of them are disposed in the n-type multilayer mirror.

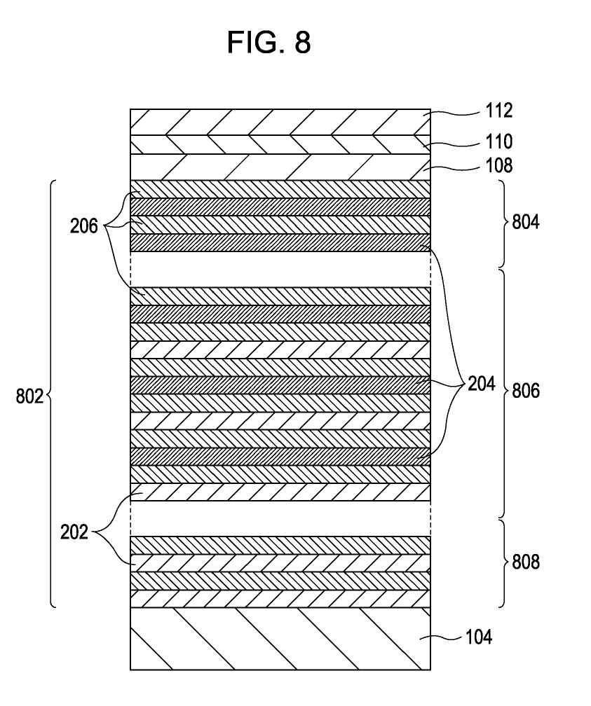

Specific arrangement configuration of these AlGaInP layers is shown in FIG. 8.

In FIG. 8, an n-type multilayer mirror 802 is divided into three regions including a region I 804, a region II 806, and a region III 808 in that order from the side nearest to the active layer, that is, the side farthest from the substrate. Here, each of the regions I, II and III is formed of 20 combinations of a low-refractive index layer and a high-refractive index layer. The region I nearest to the active layer is formed from combinations of the n-type AlAs low-refractive index layer and the n-type Al_{0.5}Ga_{0.5}As high-refractive index layer, and no AlGaInP strain compensation layer having high heat resistance is included.

In the region II, 10 structures basically composed of 1 layers of n-type AlAs low-refractive index layer/n-type Al_{0.5}Ga_{0.5}As high-refractive index layer pair and 1 layer of n-type AlAs low-refractive index layer/n-type AlGaInP strain compensation layer pair are stacked periodically. Put another way, 10 structures basically composed of 2 pairs are stacked to form region II.

The region III is formed from combinations of the n-type AlAs low-refractive index layer and the n-type AlGaInP strain compensation layer.

In the n-type multilayer mirror 802, therefore, the AlGaInP strain compensation layer is not included in the region I, 10 layers are included in the region II, and 20 layers are included in the region III. Accordingly, 30 strain compensation layers are included in total in the n-type multilayer mirror 802 of FIG. 8. The total number of the AlGaInP layers becomes equal to the value in Example 1, and the amount of accumulated strain becomes nearly equal to zero as in Example 1.

In a p-type multilayer mirror, 30 groups are formed from combinations of the p-type Al_{0.9}Ga_{0.1}As low-refractive index layer and the p-type Al_{0.5}Ga_{0.5}As high-refractive index layer, and no AlGaInP layer is included.

As described above, in the present example, the AlGaInP layers, which are necessary from the viewpoint of strain compensation and which have high heat resistance, are disposed at locations far from the active layer and are disposed in the n side because better electrical conductivity is obtained easily.

Consequently, the surface emitting laser element can be realized, wherein an occurrence of warping of the substrate is eliminated and, in addition, degradation of element characteristics is reduced.

### Example 4

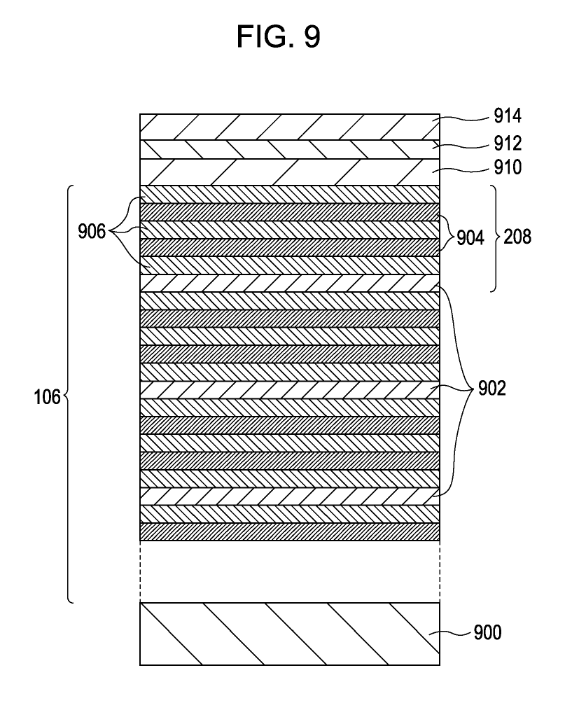

In Example 4, an n-type multilayer mirror used for a vertical cavity surface emitting laser, which lases at 400 nm, will be described with reference to FIG. 9.

The n-type multilayer mirror 106 has a structure, in which 60 pairs of n-type Al_{0.2}Ga_{0.8}N low-refractive index layer 906 and n-type GaN high-refractive index layer 904 serving as main constituent layers and each having an optical thickness of a quarter wavelength of the lasing wavelength of 400 nm are stacked.

Here, one n-type AlGaInN strain compensation layer 902 is inserted every 3 pairs of AlGaN multilayer mirrors, so as to replace one n-type Al_{0.2}Ga_{0.8}N low-refractive index layer 906.

This is the strain compensation unit structure 208. The n-type multilayer mirror 106 including 60 pairs is achieved by stacking the structures 208 by 20 units.

Then, the strain in this strain compensation unit structure will be described.

The optical thickness of a quarter wavelength of the Al_{0.2}Ga_{0.8}N low-refractive index layer is 41.8 nm and the amount of strain is 0.49% in a tensile direction. The optical thickness of a quarter wavelength of the GaN high-refractive index layer is 39.4 nm and the strain is 0% in order to lattice-match to the n-type GaN substrate 900. Here, the AlGaInN layer for strain compensation is adjusted in such a way as to have the same refractive index as that of the GaN high-refractive index layer and, therefore, the optical thickness of a quarter wavelength thereof is 39.4 nm. On the other hand, the tensile strain is 1.6%.

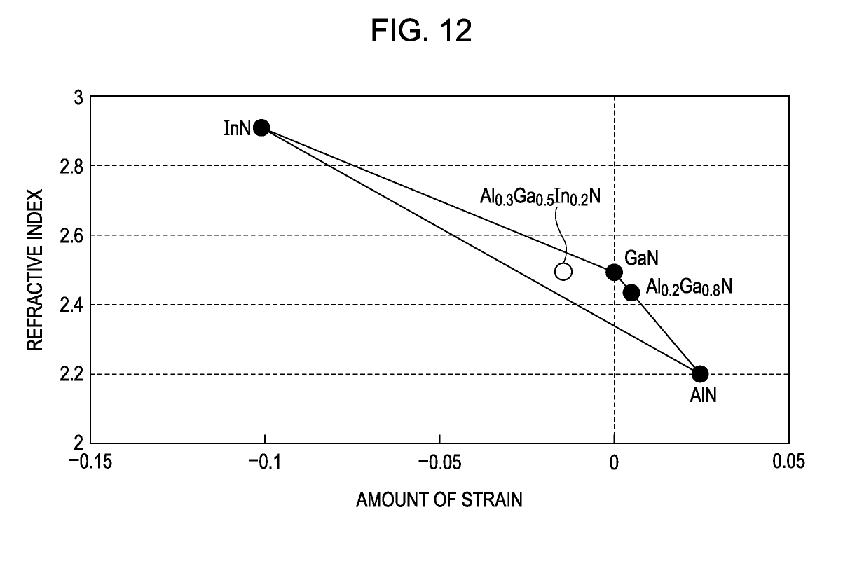

In order to have such a strain, for example, as for the In composition of the AlGaInN layer, about 20% may be employed; as for the Al composition, about 30% may be employed; and as for the Ga composition, about 50% may be employed. An example of the relationship between the strain and the refractive index is shown in FIG. 12. As shown in FIG. 12, the refractive index (vertical axis) of the Al_{0.3}Ga_{0.5}In_{0.2}N strain compensation layer is the same as that of the GaN high-refractive index layer. Furthermore, it is clear from comparison with the sum of the strain (horizontal axis) of the GaN high-refractive index layer and the strain of the Al_{0.2}Ga_{0.8}N low-refractive index layer that the direction of the strain of this Al_{0.3}Ga_{0.5}In_{0.2}N strain compensation layer is reverse and the absolute value thereof is larger than the sum.

In the above-described case, the amount of accumulated strain in the strain compensation unit structure is determined by using the left side of Formula 1 described above.

0.49×0.0418×3+0×0.0394×2+(−1.6)×0.0394×1=−0.0016%·μm

Here, 60 pairs are used for the multilayer mirrors, so that 20 strain compensation unit structures described above are required. In the case where the AlGaInN strain compensation layers are noted, 20 layers are employed. Therefore, the amount of accumulated strain of the whole element becomes −0.032%·μm.

The accumulated strain in a usual case without strain compensation is 1.2%·μm and, therefore, the accumulated strain is reduced by a factor of 50. In the case where a 3-inch substrate is assumed, the gap at the wafer center due to wafer warping is reduced significantly to 0.6 μm.

In addition, an occurrence of cracking of AlGaN due to the tensile strain, which may cause degradation of crystallinity, can be prevented.

By the way, it is necessary that the multilayer mirror has the electrical conductivity in order to facilitate current injection into the active layer. Regarding the n-type multilayer mirror 106, in order to obtain n-type conductivity, the AlGaN layer, the GaN layer, and the AlGaInN strain compensation layer are doped with Si or Se.

In order to further reduce the electrical resistance, a compositionally graded layer may be disposed between the two different refractive index layers. In order to reduce the electrical resistance while optical absorption is reduced, modulation doping, in which the amount of doping is reduced in the vicinity of the antinode of light intensity distribution and the amount of doping is increased at the node, and the like may be employed.

The active layer 912 has a multiple quantum well structure formed from a plurality of GaInN quantum well layers and a plurality of GaN barrier layers. The layer thicknesses of a p-type AlGaN spacer layer 914 and an n-type AlGaN spacer layer 910 are adjusted in such a way that the multiple quantum well structure is located at the antinode of an internal light standing wave.

As for a resonator formed from them, the layer thickness is adjusted in such a way as to have an optical thickness of an integral multiple of the lasing wavelength of 400 nm.

The wavelength of the light emitted from the active layer in itself is adjusted and produced in such a way as to have a light emission peak wavelength (for example, 390 to 400 nm) in the shorter wave side as compared with the resonant wavelength of the surface emitting laser resonator.

As described above, in the present example, if the material system is changed, the direction of introduction of the strain and the magnitude are changed. Even in such a case, a sufficient effect is exerted.

### Example 5

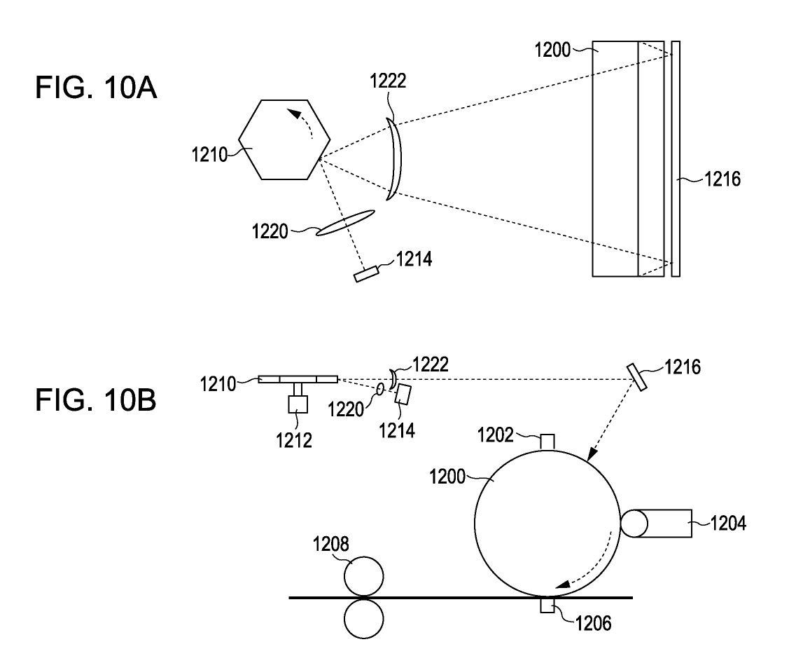

In Example 5, a configuration example of an optical apparatus formed by applying the vertical cavity surface emitting laser according to the present invention will be described with reference to FIG. 10.

Regarding the optical apparatus, a configuration example of an image forming apparatus formed by using the red surface emitting laser array on the basis of the vertical cavity surface emitting laser according to the present invention will be described here.

FIG. 10A is a top view of the image forming apparatus, and FIG. 10B is a side view of the image forming apparatus. In FIGS. 10A and 10B, reference numeral 1200 denotes a photo conductor, reference numeral 1202 denotes a charger, reference numeral 1204 denotes a developing device, reference numeral 1206 denotes a transfer charger, reference numeral 1208 denotes a fixing device, reference numeral 1210 denotes a rotatable polygonal mirror, and reference numeral 1212 denotes a motor.

Furthermore, reference numeral 1214 denotes a red surface emitting laser array, reference numeral 1216 denotes a reflector, reference numeral 1220 denotes a collimator lens, and reference numeral 1222 denotes an f-θ lens.

The image forming apparatus in the present example is configured to enter light from a light source, to which the vertical cavity surface emitting laser according to the present invention is applied, onto the photo conductor, so as to form an image.

Specifically, the motor 1212 shown in FIG. 10B is configured to drive and rotate the rotatable polygonal mirror 1210.

In this regard, the rotatable polygonal mirror 1210 in the present example is provided with six reflective surfaces. The red surface emitting laser array 1214 serves as a light source for recording.

The red surface emitting laser array 1214 is turned on or turned off by a laser driver (not shown in the drawing) in accordance with an image signal. The thus modulated laser light is applied from the red surface emitting laser array 1214 through the collimator lens 1220 toward the rotatable polygonal mirror 1210.

The rotatable polygonal mirror 1210 is rotated in the direction indicated by an arrow. The laser light output from the red surface emitting laser array 1214 is reflected as a polarized beam, where the angle of outgoing beam is continuously changed at a reflective surface of the rotatable polygonal mirror 1210 along with the rotation thereof.

This reflected light undergoes correction of distortion and the like by the f-θ lens 1222, is applied to the photo conductor 1200 through the reflector 1216, and is allowed to scan on the photo conductor 1200 in the main scanning direction. At this time, a plurality of lines of images in accordance with the red surface emitting laser array 1214 are formed in the main scanning direction of the photo conductor 1200 by reflection of a light beam through one surface of the rotatable polygonal mirror 1210.

In the present example, the red surface emitting laser array 1214 of 4×8 is used and, thereby, 32 lines of images are formed at the same time.

The photo conductor 1200 is charged in advance by the charger 1202, and is exposed sequentially by scanning of the laser light, so that an electrostatic latent image is formed.

Furthermore, the photo conductor 1200 is rotated in the direction indicated by the arrow, the resulting electrostatic latent image is developed with the developing device 1204, and the developed visible image is transferred to a transfer sheet (not shown in the drawing) with the transfer charger 1206.

The transfer sheet, to which the visible image has been transferred, is conveyed to the fixing device 1208. After fixing is conducted, the transfer sheet is discharged out of the device.

In this regard, in the present example, the red surface emitting laser array of 4×8 is used, although not limited to this. A red surface emitting laser array of m×n (m and n: natural number) may be employed.

As described above, in the case where the red surface emitting laser array according to the present example is used for an image forming apparatus of electrophotographic recording system, an image forming apparatus capable of performing high-speed, high-definition printing can be obtained.

In the above description, the example, in which the image forming apparatus is formed as the optical apparatus, is explained. However, the present invention is not limited to such a configuration.

For example, optical apparatuses, e.g., projection displays, may be formed, wherein a light source formed by applying the vertical cavity surface emitting laser according to the present invention is used, and image is displayed by entering the light from the light source onto an image display member.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-178992 filed Jul. 31, 2009, which is hereby incorporated by reference herein in its entirety.

What is claimed is:

1. A surface emitting laser comprising:
a pair of multilayer mirrors disposed opposing to each other; and
an active layer disposed between the multilayer mirrors,
wherein, in at least one multilayer mirror of the pair of multilayer mirrors,
a plurality of first pair layers are stacked, each first pair layer being formed from a high-refractive index layer having a first strain and a low-refractive index layer having a second strain, and
a second pair layer is included, the second pair layer being formed of one of the high-refractive index layer and the low-refractive index layer of the first pair layer in which one of the high-refractive index layer and the low-refractive index layer of the first pair layer is replaced with a layer formed from a quaternary or higher mixed crystal semiconductor material having a third strain,
the sum of the first strain and the second strain is a compressive or tensile strain, and
the third strain is reverse to the sum of the first strain and the second strain and the absolute value of the third strain is larger than the absolute values of the first strain and the second strain.

2. The surface emitting laser according to claim 1, wherein the high-refractive index layer and the low-refractive index layer in the first pair layer are formed from a binary semiconductor material or a ternary semiconductor material.

3. The surface emitting laser according to claim 1, wherein in the second pair layer, the high-refractive index layer in the first pair layer is replaced with the layer formed from the mixed crystal semiconductor material.

4. The surface emitting laser according to claim 1, wherein the quaternary or higher mixed crystal semiconductor material in the second pair layer comprises Al and P.

5. The surface emitting laser according to claim 1,
wherein the first pair layer is formed from AlGaAs layers and the sum of the first strain and the second strain is a compressive strain, and
the layer of quaternary or higher mixed crystal semiconductor material in the second pair layer is formed from an AlGaInP layer and the third strain is a tensile strain.

6. The surface emitting laser according to claim 1,
wherein the first pair layer is formed from AlGaN layers and the sum of the first strain and the second strain is a tensile strain, and
the layer of quaternary or higher mixed crystal semiconductor material in the second pair layer is formed from an AlGaInN layer and the third strain is a compressive strain.

7. The surface emitting laser according to claim 1, wherein in the pair of multilayer mirrors disposed opposing to each other, a larger number of first pair layers are disposed in the side nearer to the active layer.

8. The surface emitting laser according to claim 1, wherein the multilayer mirror constitutes an n-type or p-type multilayer mirror, and the second pair layer is included only in a multilayer mirror constituting the n-type.

9. A laser array comprising an array of surface emitting lasers, in which each of the surface emitting lasers is configured according to the surface emitting laser defined in claim 1.

10. An optical apparatus comprising a light source, wherein the surface emitting laser array according to claim 9 is included as the light source.
